(19) United States
(12) Patent Application Publication
(10) Pub. No.: US 2025/0040289 A1
(43) Pub. Date: Jan. 30, 2025

(54) INFRARED PHOTODETECTOR WITH ENHANCED ELECTRON EXTRACTION

(71) Applicants: Centre National de la Recherche Scientifique, PARIS (FR); Sorbonne Université, PARIS (FR)

(72) Inventors: Emmanuel LHUILLIER, PARIS (FR); Eva IZQUIERDO, ANTHONY (FR); Prachi RASTOGI, MORADABAD (IN); Charlie GRÉBOVAL, PARIS (FR)

(21) Appl. No.: 18/717,961

(22) PCT Filed: Dec. 8, 2021
(86) PCT No.: PCT/IB2021/000954

§ 371 Date: Jun. 7, 2024

(51) Int. Cl. H01L 31/0384; H01L 27/146; H01L 31/0336

(52) U.S. Cl. CPC H01L 31/0384; H01L 31/0336; H01L 27/14649

(57) ABSTRACT

The invention relates to an infrared photodetector (1), comprising an electron transport layer (4) and an infrared photon absorption layer (5) for generating an electrical signal, characterized in that the electron transport layer (4) comprises nanocrystals of a compound selected from SnO₂, ZnO, CdS, CdSe, aluminium-doped zinc oxide, Cr₂O₃, CuO, CuO₂, Cu₂O₃, ZrO₂, and mixture thereof and heterostructure thereof and alloy thereof, and in that the infrared photon absorption layer (5) comprises nanocrystals of a compound selected from HgS, HgSe, HgTe, PbS, PbSe, PbTe, Ag₂S, Ag₂Se, Ag₂Te, InAs, InGaAs, and InSb, and mixture thereof, and heterostructure thereof and alloy thereof.

The invention relates to a device used for the detection of infrared light, and in which the active layer consists in particular of HgTe nanocrystals. More precisely, the invention concerns the design of a photodiode absorbing in the range of 1 to 2.5 μm.

Infrared detectors are based on different component geometries. Photoconductors, phototransistors and photodiodes are the most common. The latter geometry is often the one that leads to the highest signal to noise ratio. Typically, photodiodes are based on a vertical stack of layers.

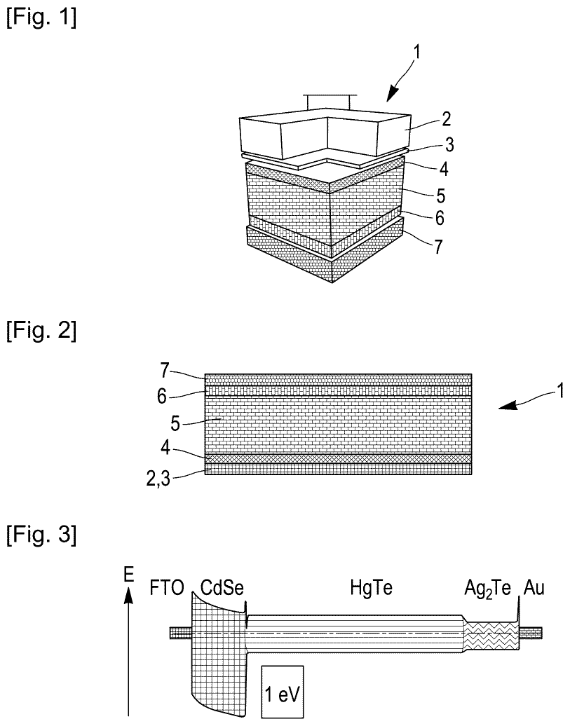

When a photodiode is made from colloidal nanocrystals, a photodiode 1 is generally based on a stack of six layers, as shown in FIG. 1:
a mechanical substrate 2 with optical transparency constraints,
a partially transparent and conductive contact 3, often made of transparent oxide such as ITO (for “indium tin oxide”),
an electron transport layer 4 for electron extraction,
a layer 5 which absorbs the incident photons and whose role is to generate an electrical signal,
a hole transport layer 6, which is used to extract the holes,
a metal contact 7 which is used as a charge collector and generally also as a backside mirror.

The vast majority of studies relative to HgTe nanocrystals based photodiode to date have focused on the hole transport layer. For example, Ackerman et al. in ACS Nano 2018, 12, 7264 optimized this layer. They integrated a layer composed of Ag₂Te nanocrystals undergoing a chemical process (cation exchange with Hg) as an electron extraction layer. The latter works particularly well when coupled to an absorber layer with a cut-off wavelength above 2.5 μm. The HgTe nanocrystals used with optical properties above 2.5 μm are large size particles (>8 nm) and their majority carriers are electrons. It is therefore essential to focus on the extraction of holes, which are the minority carriers.

The invention is particularly concerned with lower cut-off wavelengths (between 1.7 and 2.5 μm), where the HgTe nanocrystals acquire a p character. This means that the majority carriers are holes (ACS Photonics 2018, 5, 4569). As a result, the ITO/HgTe/Ag₂Te/Au stack diode is no longer as efficient in this new wavelength range. Indeed, it is no longer a pn junction but a simple Schottky junction. It is therefore essential to introduce an electron extraction layer in order to make high-performance diodes based on HgTe nanocrystals in this spectral range.

There are two examples in the literature of electron extraction layers that have been coupled to absorbing layers of HgTe nanocrystals.

In Adv. Funct. Mater. 16, 1095 (2006) by Guines et al or in J. Phys Chem C 122, 14979 (2018), by Jagtap et al combines HgTe nanocrystals with a TiO₂ layer, the latter being classically used in solar cells. The I-V curve obtained shows a strong rectifying behavior, but the responses are very low (<1 mA.W⁻¹), which makes them very poor detectors. TiO₂ is a large band gap n-type oxide. Its band alignment makes hole blocking efficient, which leads to the observed shape of the I-V curves. However, the residual offset between the conduction bands of TiO₂ and HgTe makes this layer also filters the generated photoelectrons, which reduces the photoresponse.

In Small 2019, 15, 1804920. Tang et al proposes to use a layer of Bi₂Se₃ nanoparticles as an electron extraction layer coupled to a layer of absorber nanocrystals in the spectral range of interest. This strategy led to more interesting performances, but the large size of the Bi₂Se₃ nanoplatelets makes it difficult to obtain a homogeneous layer, i.e. without short-circuiting. In addition, the low band gap of Bi₂Se₃ leads to inefficient filtration of the dark hole current, which limits the rectifying character of the I-V curve.

The present invention aims to remedy these drawbacks.

The object of the invention is thus an infrared photodetector, comprising an electron transport layer and an infrared photon absorption layer for generating an electrical signal. The presence of the electron transport layer (ETL) allows the charge carrier transport properties to be optimized.

In the photodetector according to the invention, the electron transport layer comprises nanocrystals of a compound selected from SnO₂, ZnO, CdS, CdSe, aluminium-doped zinc oxide, Cr₂O₃, CuO, CuO₂, Cu₂O₃, ZrO₂, and mixture thereof, and heterostructure thereof and alloy thereof, and the infrared photon absorption layer comprises nanocrystals of a compound selected from HgS, HgSe, HgTe, PbS, PbSe, PbTe, Ag₂S, Ag₂Se, Ag₂Te, InAs, InGaAs and InSb and mixture thereof and heterostructure thereof and alloy thereof.

Particularly preferably, the infrared photon absorption layer comprises HgTe nanocrystals and the electron transport layer comprises CdSe or SnO₂ nanocrystals.

This electron transport layer has a band alignment which is particularly well suited to allow electron extraction from an absorption layer consisting of HgTe.

The introduction of an electron transport layer facilitates the extraction of electrons while reducing the dark current associated with holes. It therefore contributes to the formation of the pn junction in this component, which induces an internal electric field that will participate in charge dissociation, even in the absence of applied voltage. The use of CdSe or SnO₂ allows high responses to be obtained thanks to a more favorable band alignment.

The offset between the conduction band of the electron transport layer and the conduction band of the infrared photon absorption layer is preferably less than 1 eV, more preferably less than 0.3 eV and most preferably less than 0.1 eV.

The photodetector may comprise:
a mechanical substrate layer,
an electron contact layer constituting a top electrode,
the electron transport layer,
the infrared photon absorption layer for generating an electrical signal,
a hole transport layer,
a metallic contact layer for collecting charges, which forms a bottom electrode.

The stacking order of the layers may be as described above. In one other embodiment the electron transport layer and the hole transport layer are inverted.

A nanocrystal-based photodiode can thus be obtained on the basis of a stack of layers, in which the absorbing layer is surrounded by a hole transport layer and an electron transport layer which are introduced to selectively promote the extraction of holes and electrons respectively. In addition, two electrodes are added whose role is to extract the photocharge carrier. One of these electrodes is partially transparent in the spectral range of interest to allow light to penetrate the absorbing layer.

The mechanical substrate layer may comprise a compound selected from glass, CaF₂, undoped Si, undoped Ge, ZnSe, ZnS, KBr, LiF, Al₂O₃, KCl, BaF₂, CdTe, NaCl, CsBr, MgF₂, quartz, CdZnTe, InP, GaAs, thalium bromoiodide, and heterostructure thereof and alloy thereof.

The electronic contact layer may have a thickness of between 1 and 10 μm, and preferably between 10 nm and 3 μm.

The electron transport layer may have a thickness of between 0.5 and 500 nm.

The infrared photon absorption layer may have a thickness of between 1 nm and 3 μm, preferably of between 1 nm and 1 μm.

The infrared photon absorption layer may have an optical gap between 1 and 3 μm, and preferably between 1.5 and 2.5 μm.

The hole transport layer may have a thickness of between 0.5 nm and 500 nm.

The metallic contact layer may have a thickness of between 1 and 10 μm, and preferably of between 10 nm and 3 μm.

The photodetector may be a photodiode.

The infrared photon absorption layer may be coupled to a light resonator.

The invention also relates to an imaging device. The imaging device according to the invention comprises a plurality of photodetectors described above, configured to form an image.

In the imaging device according to claim, the plurality of photodetectors may be coupled to a readout circuit, for example of CMOS technology.

The invention also relates to a camera device. The camera device comprises a plurality of photodetectors described above, configured to form a camera.

In the camera device, the plurality of photodetectors may be coupled to an electronic system, an optical system, and a temperature control system.

Further advantages and features of the present invention will be apparent from the following description, which is given as a non-limiting example with reference to the attached figures:

FIG. 1, already described, is a perspective view of an infrared photodetector,

FIG. 2 is a schematic of an infrared photodetector according to the invention with electron contact layers, an electron transport layer, a photoactive layer, and a hole transport layer,

FIG. 3 is a diagram showing the alignment of the bands in each layer with CdSe as the electron transport layer,

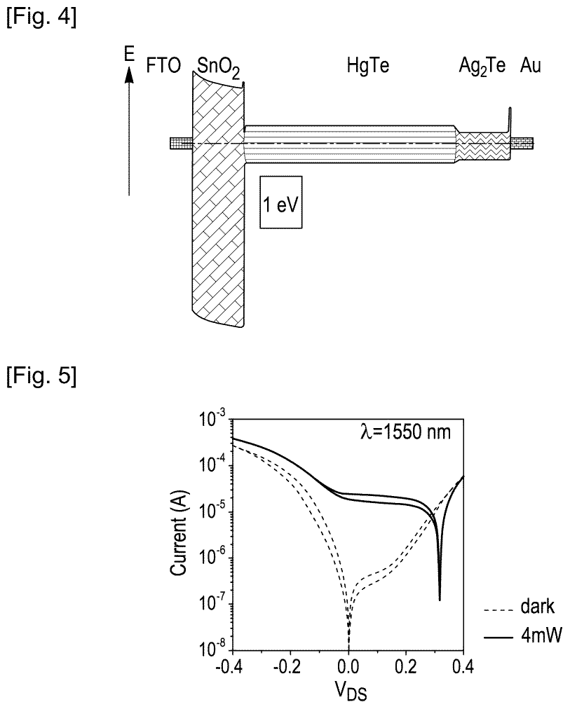

FIG. 4 is a diagram showing the band alignment of each layer with SnO₂ as the electron transport layer,

FIG. 5 is a graph showing the current-voltage curves in the dark and under illumination (1550 nm at 4 mV) of a photodetector without electron transport layer,

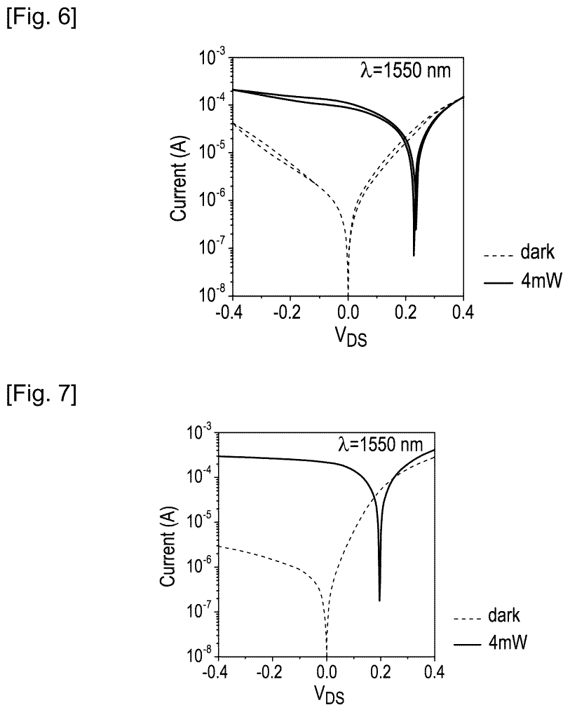

FIG. 6 is a graph showing the current-voltage curves in the dark and under illumination (1550 nm at 4 mV) of a photodetector with an electron transport layer in CdSe,

FIG. 7 is a graph showing the current-voltage curves in the dark and under illumination (1550 nm at 4 mV) of a photodetector with an electron transport layer in SnO₂,

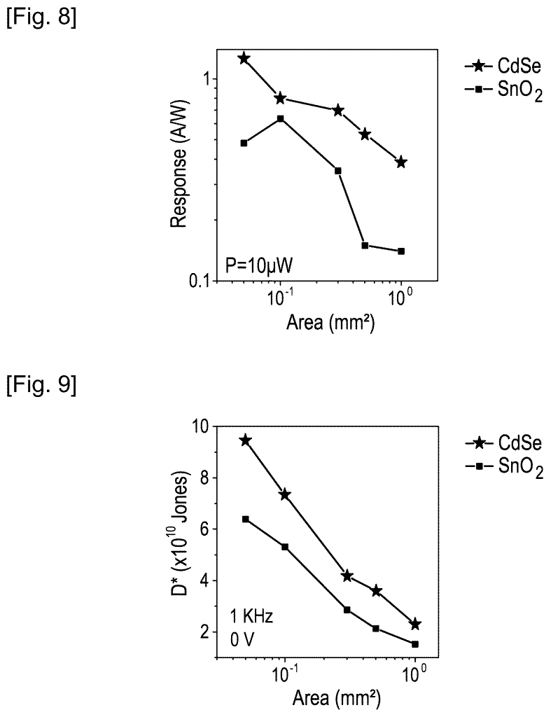

FIG. 8 is a graph comparing the photoresponse for a photodetector with CdSe and SnO₂ as electron transport layer and for different pixel areas,

FIG. 9 is a graph comparing the detectivity for a photodetector with CdSe and SnO₂ as electron transport layer and for different pixel areas,

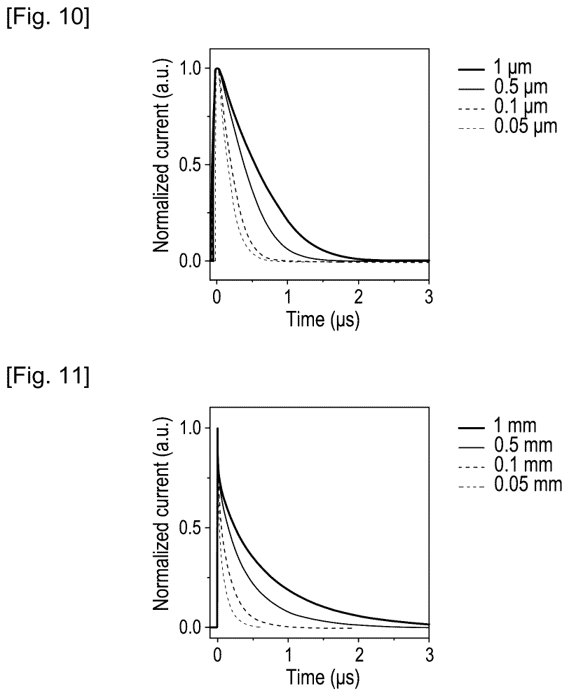

FIG. 10 is a graph showing the time response for a photodetector with CdSe as the electron transport layer and for different pixel areas,

FIG. 11 is a graph showing the time response for a photodetector with SnO₂ as the electron transport layer and for different pixel areas,

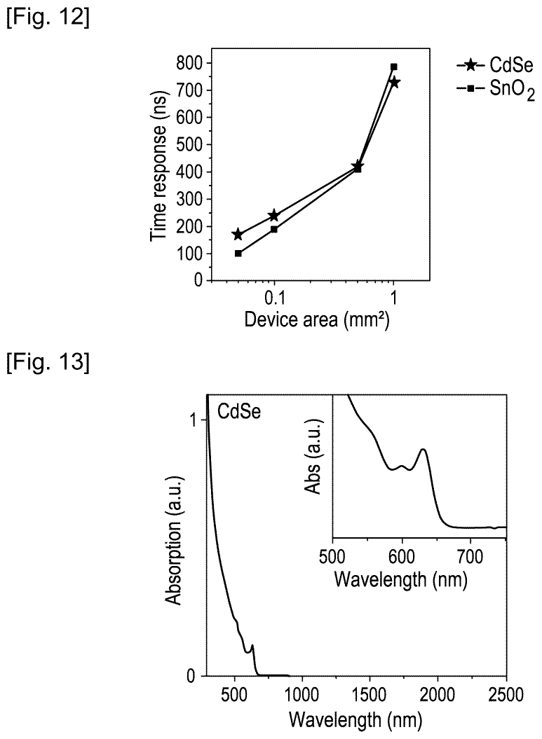

FIG. 12 is a graph comparing the response time for a photodetector with CdSe and SnO₂ as electron transport layers and for different pixel area,

FIG. 13 is a graph illustrating the absorption spectra of CdSe,

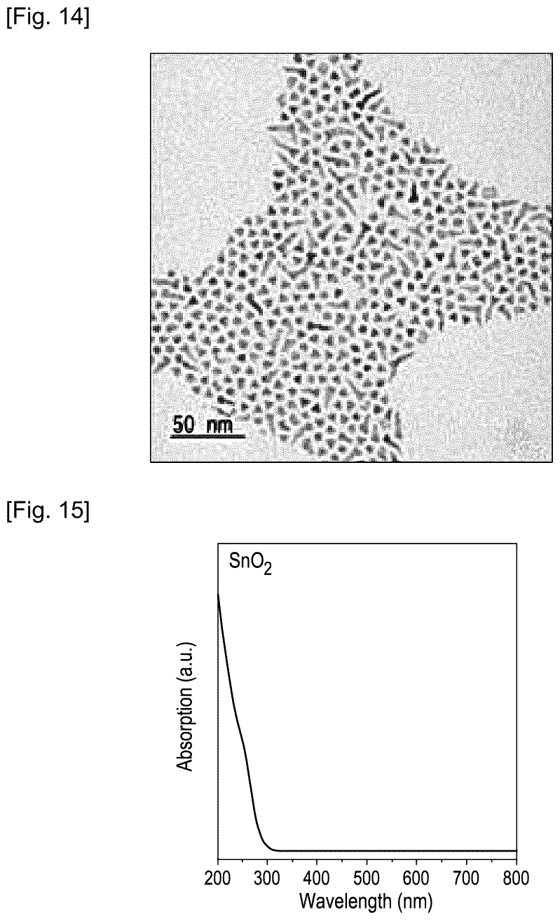

FIG. 14 is a transmission electron microscope image of CdSe nanocrystals,

FIG. 15 is a graph showing the absorption spectra of SnO₂,

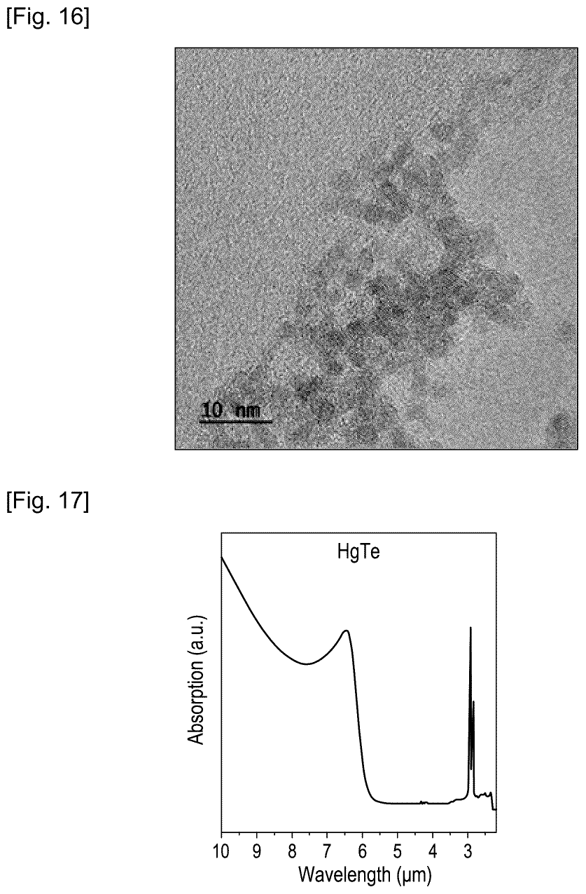

FIG. 16 is a transmission electron microscope image of SnO₂,

FIG. 17 is a graph showing the absorption spectra of HgTe nanocrystals with a band edge at around 6000 cm⁻¹ (720 meV),

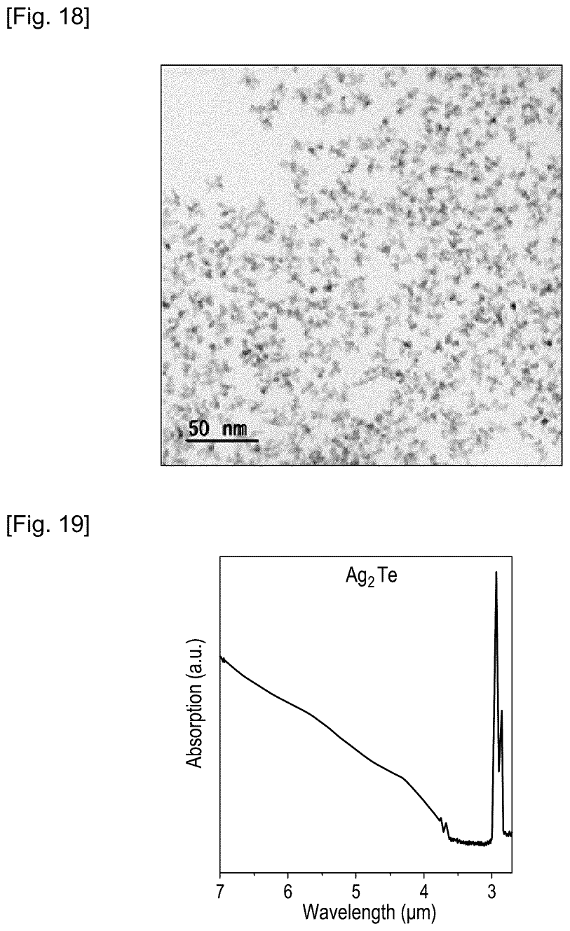

FIG. 18 is a transmission electron microscope image of HgTe nanocrystals with a band edge at around 6000 cm⁻¹ (720 meV),

FIG. 19 is a graph showing the absorption spectra of Ag₂Te nanocrystals,

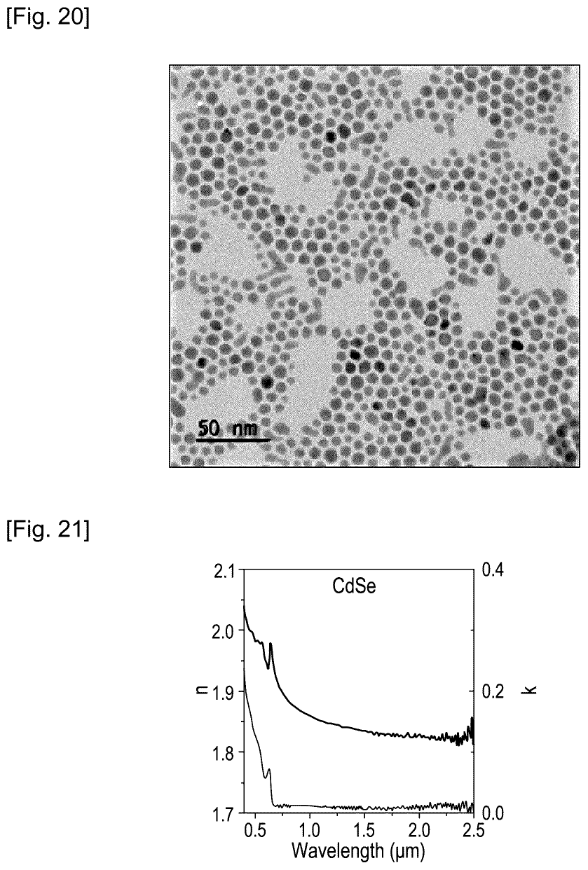

FIG. 20 is a transmission electron microscope image of Ag₂Te nanocrystals,

FIG. 21 is a graph showing the complex optical index for a film of CdSe nanocrystals,

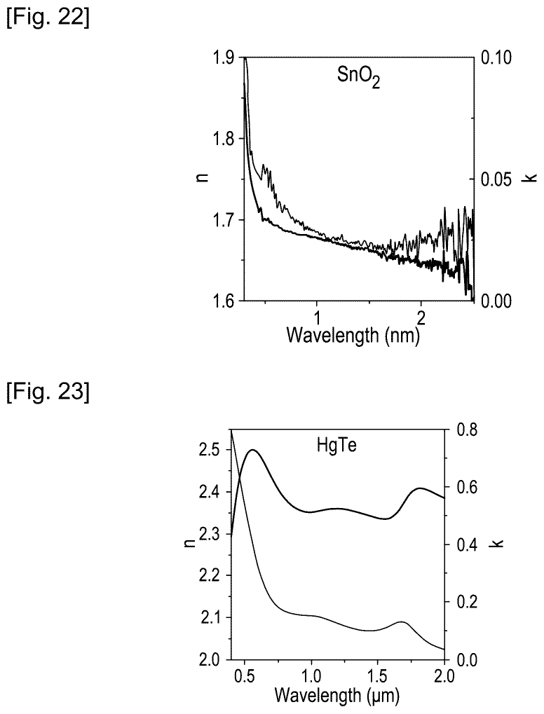

FIG. 22 is a graph showing the complex optical index for a film of SnO₂, and

FIG. 23 is a graph showing the complex optical index for a HgTe film.

### DESCRIPTION DETAILLEE

As illustrated in FIG. 2, a photodetector 1 according to the invention, such as a photodiode, advantageously comprises, arranged vertically and successively
a mechanical substrate 2 with generally optical transparency constraints,
a partially transparent and conductive contact 3, often made of transparent oxide such as ITO, which constitutes an upper electrode (first electronic contact layer),
an electron extraction layer 4 (electron transport layer),
a layer 5 which absorbs incident photons and whose role is to generate an electrical signal,
a hole transport layer 6,
a metallic contact 7 which serves to collect charges and also as a backside mirror, and which constitutes a bottom electrode (second electron contact layer).

The stacking order of the layers may be as described above. In one other embodiment the electron transport layer 4 and the hole transport layer 6 are inverted.

The invention relates in particular to photodiodes in which the layer absorbing the incident photons is made of mercury chalcogenide nanocrystals, in particular HgTe, and whose optical gap is between 1 and 3 μm, and more preferably between 1.5 and 2.5 μm.

Two embodiments are proposed based on CdSe and SnO₂ for the electron transport layer. These embodiments allow improved performance. Indeed, the band alignment is specific, i.e. has a large deviation from the valence band of HgTe, while having a conduction band resonant with that of HgTe. The material used is a semiconductor with a band gap larger than that of the HgTe nanocrystals used for absorption.

To avoid forming a mismatch between the conduction bands, it is preferable that CdSe be as unconfined as possible. It is therefore advantageous to grow large CdSe particles (>6 nm) giving a band gap around 650 nm. In addition, to make the layer as conductive as possible, its surface chemistry is advantageously modified by very short ions (S²-) and this layer is annealed at a relatively high temperature (200° C.), to induce sintering of the layer.

The invention allows increased detection performance with a response of 0.8 A.W⁻¹, which corresponds to an external quantum efficiency of 50% and 100% for the internal quantum efficiency. The signal to noise ratio, given by the specific detectivity, reaches 9×10¹¹ Jones at room temperature and 9×10¹² Jones at 200 K.

In the targeted spectral range (typically between 1 and 1.7 μm), the dominant technology is based on the InGaAs semiconductor. This is a high-performance technology: low dark current, high quantum efficiency around 80%, very good homogeneity. However, it has certain limitations. Indeed, InGaAs is manufactured by epitaxy on an InP substrate that absorbs light below 900 nm. As a result, InGaAs does not absorb visible light, which means that a complementary camera is needed to image the visible part of the spectrum. Attempts have been made to refine the substrate a posteriori, but this remains in the research stage. Epitaxy also dictates the cut-off wavelength of the material (1.8 μm at room temperature and 1.65 μm when cold). Indeed, the composition of the InGaAs alloy is optimized so that the lattice parameter of InGaAs is the same as that of the InP substrate. It is therefore difficult to extend the spectral range of InGaAs. In contrast, the nanocrystals used in the photodetector according to the invention do not have this epitaxial constraint and it is therefore very easy to adjust their cut-off wavelength in the 1-5 μm range.

Another limitation of InGaAs is its cost. The cost of InGaAs is due to the epitaxial growth and the hybridization coupling step using small indium beads between the III-V semiconductor and the readout circuit. The yield of this process is low, which increases the cost. A second limitation of this hybridization step is that it makes difficult to reduce the pixel pitch. In a camera, the pixel size should ideally be very close to the diffraction limit (i.e. pixel size=cut-off wavelength). Currently for InGaAs, the pixel pitch is around 15 μm or 10 times the cut-off wavelength. Major research efforts are trying to reduce the pixel pitch to 10 μm (or even 5 μm). The use of nanocrystals makes it possible to avoid this hybridization step.

### The Photodetector

The photodetector may have a detection wavelength that is centered on a value between about 800 nm and about 5 μm, more preferably between about 1000 nm and 3 μm, even more preferably between about 1400 nm and 2.5 μm.

The photodetector may provide two-color detection and one of the wavelengths is centered at a value between about 800 nm and about 5 μm, more preferably between about 1 μm and 3 μm, still more preferably between about 1.4 μm and 2.5 μm.

The photodetector may allow for multi-colour detection.

The photodetector may have a temporal response ranging from about 1 ps to about 1 ms, more preferably from about 1 ns to about 100 ps, even more preferably from about 10 ns to about 3 ps.

The photodetector may have a response ranging from about 1 mA.W⁻¹ to about 2 A.W⁻¹, more preferably from about 10 mA.W⁻¹ to about 2 A.W⁻¹, even more preferably from about 0.1 A.W⁻¹ to about 2 A.W⁻¹.

The photodetector may have a detectivity between about 10⁶ and about 10¹⁴ Jones, more preferably between about 10⁸ and about 10¹³ Jones.

The photodetector may have a bandwidth from about 1 Hz to about 1 GHz, more preferably from about 10 Hz to about 100 MHz.

The photodetector may operate at a temperature ranging from about 4 K to about 350 K, preferably from about 50 K to about 310 K, more preferably from about 70 K to about 300 K.

The photodetector may be illuminated from the front or the back side.

The substrate

The substrate may be electrically insulating.

The resistivity of the substrate may be greater than about 100Ω.cm.

The substrate may be partially or fully optically transparent in the infrared range.

The substrate may be partially or fully optically transparent from about 800 nm to about 5 μm, more preferably from about 1 μm to 3 μm, even more preferably from about 1 μm to 2.5 μm.

The substrate may have an optical transmission ranging from about 0% to about 100%, more preferably from about 50% to about 100%, still more preferably from about 80% to 100%.

The substrate may comprise, but is not limited to, glass, CaF₂, undoped Si, undoped Ge, ZnSe, ZnS, KBr, LiF, Al₂O₃, KCl, BaF₂, CdTe, NaCl, CsBr, GaAs, MgF₂, CdZnTe, InP, GaAs, quartz, KRS-5 (thalium bromoiodide), a stack thereof, or a mixture thereof or a heterostructure thereof.

### Electronic Contact Layers

Each electronic contact layer may be a metallic contact.

The electronic contact layers may have a thickness of between about 1 nm and about 200 nm, more preferably between about 5 nm and 100 nm.

One of the electronic contact layers may be partially or fully optically transparent in the infrared range.

One of the electronic contact layers may be partially or fully optically transparent from about 800 nm to about 5 μm, more preferably from about 1 μm to 3 μm, even more preferably from about 1.4 μm to 2.5 μm.

The electronic contact layers may include, but are not limited to, Au, Ag, Al, Ni, W, Ti, Cr, Pt, Cu, ITO or FTO.

One of the electron contact layers may be used as an electron extractor and the other may be used as a hole extractor.

The electron contact layers may have a work function of from about 6 eV to about 3 eV, more preferably from about 5.5 eV to 4 eV.

The electron contact layers may be obtained by thermal evaporation, sputtering or optical lithography.

### The Electron Extraction Layer (Electron Transport Layer)

The electron transport layer is advantageously made of a material whose conduction band has a small offset with the conduction band of the HgTe nanocrystals having a band gap energy between 1.4 and 2.5 μm. The offset between the conduction band of the electron transport layer and the absorbing layer is typically less than 1 eV, preferably less than 0.3 eV and more preferably less than 0.1 eV.

The electron transport layer may be used to extract electrons from the photoactive layer.

The electron transport layer may have a work function between about 5.5 eV and about 3 eV, more preferably between about 5 eV and 3.5 eV.

The electron transport layer may have an optical transmission ranging from about 0% to about 100%, more preferably from about 50% to about 100%, even more preferably from about 80% to 100%.

The electron transport layer may have an electron mobility ranging from about 10⁻⁴ cm².V⁻¹.s⁻¹ to about 50 cm².V⁻¹.s⁻¹, more preferably from about 0.01 cm².V⁻¹.s⁻¹ to about 5 cm².V⁻¹.s⁻¹.

The electron transport layer may have a real optical index between about 1 and about 4, more preferably between about 1.4 and about 2.5.

The electron transport layer may have a thickness ranging from about 0.5 nm to about 500 nm, more preferably from about 5 nm to about 250 nm, even more preferably from about 10 nm to about 100 nm.

The nanocrystals of the electron extraction layer may have a size ranging from about 0.5 nm to about 100 nm, more preferably from about 1 nm to about 50 nm, even more preferably from about 2 nm to about 20 nm.

The electron transport layer may be obtained by drop-casting, spin-coating, spray-coating, ink-jet, nanoimprinting, dip-coating, doctoring, Langmuir-Blodgett method, electrophoretic procedure, thermal evaporation, or sputtering.

The electron transport layer may comprise, but is not limited to, SnO₂, ZnO, CdS, CdSe, AZO (aluminium-doped zinc oxide), Cr₂O₃, CuO, CuO₂, Cu₂O₃, ZrO₂, and mixture thereof, and heterostructure thereof and alloy thereof.

The electron transport layer may not consist of Bi₂Se₃.

### The Incident Photon Absorbinq Layer (Photoactive Layer)

The photoactive layer may be a photoabsorbent film of semiconductor nanoparticles.

The photoactive layer may be obtained by deposition of nanocrystals by drop-casting, spin-coating, spray-coating, ink-jet, nanoimprinting, dip-coating, scraping, Langmuir-Blodgett method or electrophoretic procedure.

The photoactive layer may consist of nanoparticles having infrared absorption.

The physical mechanism responsible for the infrared absorption may be an interband or intraband transition.

The semiconductor nanoparticles may have a band gap of about 0.25 eV to about 1.55 eV, more preferably about 0.41 eV to about 1.24 eV, even more preferably about 0.5 V to about 0.89 eV.

The photoabsorbent layer may have a real optical index between about 1 and about 4, more preferably between about 1.7 and about 2.8.

The size of the nanoparticles may be between about 1 nm and about 1 μm. With respect to the shape of the particles, the particles may be spheres, nanoplatelets, rods, tripods, or tetrahedra.

The nanoparticles can be a p-type semiconductor, an ambipolar semiconductor or an n-type semiconductor.

The doping of the nanocrystals may be from about 0 to about 1000 electrons per nanocrystal, more preferably from about 10⁻¹⁰ to about 100 electrons per nanocrystal, even more preferably from about 10⁻⁶ to about 1 electron per nanocrystal.

The doping level may be in particular between about 10¹⁵ cm⁻³ and about 10²¹ cm⁻³, more preferably between about 10¹⁷ cm⁻³ and about 10²⁰ cm⁻³, even more preferably between about 10¹⁸ cm⁻³ and about 10²⁰ cm⁻³.

The photoabsorbent layer may have a hole mobility between about 10⁻⁴ cm².V⁻¹.s⁻¹ and about 50 cm².V⁻¹.s⁻¹, more preferably between about 10⁻² cm².V⁻¹.s⁻¹ and about 10 cm².V⁻¹.s⁻¹.

The photoabsorbent layer may have an electron mobility between about 10⁻⁴ cm².V⁻¹.s⁻¹ and about 50 cm².V⁻¹.s⁻¹, more preferably between about 10⁻² cm².V⁻¹.s⁻¹ and about 10 cm².V⁻¹.s⁻¹.

The photoabsorbent layer may have a thickness between about 10 nm and about 1 μm, more preferably between about 100 nm and about 600 nm.

The photoactive layer may be a multilayer structure.

The photoactive layer may be a multilayer structure comprising a layer of p-type material and an ambipolar layer.

The photoactive layer may comprise, but is not limited to, HgS, HgSe, HgTe, PbS, PbSe, PbTe, Ag₂S, Ag₂Se, Ag₂Te, InAs, InGaAs or InSb and alloy thereof, and mixture thereof, and heterostructure thereof.

### The Hole Transport Layer

The hole transport layer may be made of a material whose conduction band has a low offset with the conduction band of HgTe nanocrystals having a band gap energy between 1.5 and 2.5 μm. The offset between the conduction band of the hole transport layer and the absorber layer is typically less than 1 eV, preferably less than 0.3 eV and more preferably less than 0.1 eV.

The hole transport layer may be used to extract holes from the photoactive layer.

The hole transport layer may have a work function between about 7 eV and about 3.5 eV, more preferably between about 6 eV and 4 eV.

The hole transport layer may have a hole mobility between about 10⁻⁴ cm².V⁻¹.s⁻¹ and about 50 cm².V⁻¹.s⁻¹, more preferably between about 0.01 cm².V⁻¹.s⁻¹ and about 10 cm².V⁻¹.s⁻¹.

The hole transport layer may have a thickness ranging from about 0.5 nm to about 500 nm, more preferably from about 5 nm to about 250 nm, even more preferably from about 10 nm to about 100 nm.

The hole transport layer may be obtained by drop casting, spin coating, spray coating, ink jet, nano printing, dip coating, doctoring, Langmuir-Blodgett method, electrophoretic procedure, thermal evaporation or spraying.

The hole transport layer may consist of an inorganic material.

The hole transport layer may include, but is not limited to, Ag₂Te, HgTe, PbS, MoO₃, CuSCN, V₂O₅, WO₃, NiO, CrOx, ReO₃, RuOx, Cu₂O, CuO, where x is a decimal ranging from 0 to 5, and alloy thereof, and mixture thereof, and heterostructure thereof.

The hole transport layer may consist of nanoparticles.

The hole transport layer may consist of a conductive polymer.

The hole transport layer may consist of a p-type conductive polymer.

The hole transport layer may consist of a conductive polymer such as P3HT or PEDOT:PSS.

The nanoparticles of the hole transport layer may have a size ranging from about 0.5 nm to about 100 nm, more preferably from about 1 nm to about 50 nm, even more preferably from about 2 nm to about 20 nm.

### Infrared Photodetector Applications

The photodetector may comprise a single pixel.

The photodetector may comprise a plurality of pixels.

The pixels may form a pixel line.

The pixels may form a pixel array.

The size of the pixel array may be between about 4×4 pixels and about 16384×12288 pixels, more preferably between about 320×200 pixels and about 16384×12288 pixels.

The array may have a number of pixels ranging from about 16 to about 300 M pixels, more preferably from about 1000 to about 202 M pixels.

The area of the pixels may be from about 1 nm² to about 1 mm², more preferably from about 100 nm² to about 0.1 mm².

The pitch of the pixels may be between about 0.1 μm and about 10 mm, more preferably between about 1 μm and about 1 cm.

The pixels may be non-overlapping.

Each pixel may be coupled to a readout circuit.

Each pixel may be coupled to a readout circuit in a vertical geometry.

The pixel array may be coupled to a readout circuit.

The pixel array may be coupled to a vertical geometry.

Each pixel can be coupled to a CMOS readout circuit (for «Complementary Metal Oxide Semiconductor»).

The pixel array can be coupled to a CMOS readout circuit.

Each pixel may be operated under electric field which absolute value ranges from 0 to 100 kV.cm⁻¹.

Each pixel may be operated under bias which absolute value ranges from 0 to 10 V and preferably from 0 to 3 V.

Each pixel may be operated at 0 V in photovoltaic mode.

The pixel array can be operated at 0 V in photovoltaic mode.

The photodetector can be included in an infrared camera.

The photodetector is coupled to a light resonator.

The light resonator coupled to the absorbing layer is a Fabry-Perot cavity, a grating, a guided mode resonator, a plasmonic cavity

### Results

As shown in FIGS. 3 and 4, and as determined by photoemission measurements, the resulting band alignment corresponds well to the advantages of the invention: no or little offset for the conduction bands and large offset for the valence bands. FIG. 3 shows the band structure of the photodiode based on the glass/FTO/CdSe/HgTe/Ag₂Te/Au stack, while FIG. 4 shows the band structure of the photodiode based on the glass/FTO/SnO₂/HgTe/Ag₂Te/Au stack.

The I-V (current-voltage) curve in the dark is well asymmetrical and the conduction minimum of the curve under illumination is shifted. FIG. 6 shows the I-V curve in the dark and under illumination (λ=1.55 μm-P=4 mW) of the photodiode based on the glass/FTO/CdSe/HgTe/Ag₂Te/Au stack.

In another embodiment of the invention, illustrated in FIG. 7 (Curve IV in the dark and under illumination (λ=1.55 μm-P=4 mW) of the photodiode based on the glass/FTO/SnO₂/HgTe/Ag₂Te/Au stack), the electron transport layer is made up of a doped SnO₂ layer. SnO₂ is already used for solar cells, especially those based on perovskites, but has not yet been tested for infrared photodiodes based on HgTe nanocrystals. Compared to ZnO and TiO₂, SnO₂ has a higher electron affinity (i.e. a deeper conduction band) and therefore a more favorable alignment. SnO₂ leads to an even more rectifying I-V curve while maintaining a high response (0.4 A.W⁻¹)

An attempt was made to characterize the performance of the photodiode.

It was determined that the photoresponse of these components reaches 0.8 A.W⁻¹ which corresponds to an external quantum efficiency (number of electrons generated per incident photon) of 50%. Furthermore, the absorption of this device was simulated and it was determined that the active layer absorbs 50% of the incident light.

This means that the internal quantum efficiency of this diode is close to 100% (FIG. 8).

The performance of this diode was determined by characterizing the specific detectivity (which quantifies the signal to noise ratio). The performance is above the state of the art for a HgTe based photodiode. The specific detectivity is 9×10¹⁰ Jones at room temperature and 9×10¹¹ Jones at 200 K (FIG. 9).

Moreover, the response time of this device is short (<1 ps) and can even go down to around 200 ns for small devices (FIGS. 10 and 11)

### EXAMPLES

The present invention is further illustrated by the following examples.

### Materials and Methods

1 M TOP:Te Precursor

2.54 g of Te powder was mixed with 20 mL of TOP (trioctylphosphine) in a three neck flask. The flask was kept under vacuum at room temperature for 5 min and then the temperature was increased to 100° C. In addition, the flask was degassed for the next 20 min. The atmosphere was replaced with nitrogen and the temperature was raised to 275° C. The solution was stirred until a light orange color was obtained. The flask was cooled to room temperature and the color changed to yellow. Finally, this solution was transferred to a nitrogen-filled glove box for storage.

0.1 M Se-ODE precursor

In a 100 mL three neck flask, 46.7 mL of ODE (octadecene) were degassed at room temperature for 30 minutes. During this time, a suspension of 393 mg Se in 3 mL ODE was prepared. After degassing, the atmosphere was changed to nitrogen and the temperature was raised to 170° C. The suspension was added in portions (300 μL), waiting between each addition for complete dissolution of the Se. Once all the Se was completely dissolved in the ODE, the solution was heated for 1 h at 215° C.

The solution turned reddish-orange to yellow. The flask was cooled to room temperature. The solution was transferred to a glove box.

### Cadmium Myristate Precursor

In a 100 mL three neck flask, 2.56 g CdO and 11 g myristic acid were degassed under vacuum for 30 minutes at 70° C. Under an argon flow, the mixture was heated at 200° C. for 30 minutes until the solution became colorless. Then 50 mL of MeOH was added at 60° C. to 70° C. to solubilize the excess myristic acid. The mixture was stirred for 30 minutes. At the end, the cadmium myristate was precipitated using a centrifuge tube by adding MeOH. The washing procedure was repeated at least three times. The cadmium myristate was dried overnight under vacuum.

### 0.5 M Cadmium Oleate Precursor

0.5 M cadmium oleate solution was synthesized by heating 10 mmol of cadmium oxide in 20 mL of oleic acid at 160° C. under Ar until a colorless solution was obtained. The solution was then degassed under vacuum at 100° C. for 1 h.

### Example: HqTe Nanocrystals Synthesis with Band-Edge at 6000 cm⁻¹

In a 50 mL three neck flask, 540 mg of HgCl₂ and 50 mL of oleylamine were degassed under vacuum at 110° C. At this stage, the solution was yellow and clear. Meanwhile, 2 mL of TOP:Te (1M) was extracted from the glove box and was mixed with 8 mL of oleylamine. The atmosphere was switched to N₂ and the temperature was set at 57° C. The pre-heated TOP:Te solution was quickly injected and the solution turned dark after 1 min. After 3 min, 10 mL of a mixture of 10% DDT (dodecanethiol) in toluene was injected and a water bath was used to quickly decrease the temperature. The content of the flask has been split in 4 tubes and methanol was added. After centrifugation, the formed pellets were redispersed in one tube with 10 mL of toluene. The solution was precipitated a second time with absolute ethanol.

Again, the formed pellet was redispersed in 8 mL of toluene. At this step, the nanocrystals were centrifuged in pure toluene to remove the lamellar phase. The solid phase was discarded and the supernatant filtrated.

### Example: HqTe Nanocrystals Synthesis with Band-Edqe at 4000 cm⁻¹

In a 50 mL three neck flask, 540 mg of HgCl₂ and 50 mL of oleylamine were degassed under vacuum at 110° C. At this stage, the solution was yellow and clear. Meanwhile, 2 mL of TOP:Te (1M) was extracted from the glove box and was mixed with 8 mL of oleylamine. The atmosphere was switched to N₂ and the temperature was set at 86° C. The pre-heated TOP:Te solution was quickly injected and the solution turned dark after 1 min. After 3 min, 10 mL of a mixture of 10% DDT in toluene was injected and a water bath was used to quickly decrease the temperature. The content of the flask has been split in 4 tubes and methanol was added. After centrifugation, the formed pellets were redispersed in one tube with 10 mL of toluene. The solution was precipitated a second time with absolute ethanol. Again, the formed pellet was redispersed in 8 mL of toluene. At this step, the nanocrytsals were centrifuged in pure toluene to remove the lamellar phase. The solid phase was discarded and the supernatant filtrated.

### Example: Aq₂Te Nanocrystals Synthesis

In a 25 ml three neck flask, 34 mg AgNO₃ (0.2 mM), 5 mL oleylamine and 0.5 mL oleic acid were degassed at 70° C. under vacuum until the AgNO₃ was completely dissolved and the solution became clear. Under nitrogen, 0.5 mL TOP was injected into the solution. Then temperature was raised to 160° C. At 160° C. the solution became orange. Now 0.1 mL TOPTe (1 M) was injected into the solution and the reaction was quenched after 10 min with a water bath. The nanocrystals were precipitated with methanol and redispersed in chlorobenzene. At this step, 500 μL of dodecanethiol were added. The washing step was repeated one more time and finally the nanocrystals were redispersed in hexane:octane (9:1) solution.

### Example: CdSe Nanocrystals Synthesis

In a 100 mL three neck flask, 170 mg of cadmium myristate and 7.5 mL of octadecene were degassed at room temperature for 30 min. Then, the reaction was put under nitrogen and heated up at 250° C. Meanwhile, a suspension of Se (24 mg) in 2 mL of octadecene was prepared. At 250° C., 1 mL of this solution was rapidly injected (suspension is sonicated just before the injection). Immediately after the injection, the temperature controller was set at 240° C. and the reaction is heated for 5 min. After this time, 200 μL of oleic acid have been added and the temperature controller was set at 260° C. At 260° C., 2 m L of oleylamine were added and the reaction was heated for 10 min. Meanwhile, 2 mL of cadmium oleate 0.5 M and 10 mL of Se-octadecene 0.1 M were mixed. 11 mL of the previous mixture was injected with a flow rate of 10 mL/h. Then, the reaction was left cooling down to room temperature. The reaction mixture has been split into two tubes and the round-bottomed flask was rinsed with 10 mL of Hexane which were distributed in two tubes. The particles were precipitated by adding 30 mL of ethanol in each tube. The mixtures were centrifuged at 6000 rpm for 10 min. The supernatants were discarded and both pellets (containing mainly the CdSe cores) were assembled into 10 mL of hexane. The CdSe nanocrystals were precipitated with 40 mL of ethanol. The mixture was centrifuged at 5500 rpm for 10 min. The supernatant was discarded and the pellet was dispersed into 10 mL of hexane.

### Example: Liqand Exchange Procedure for HqTe Nanocrystals

1 mL of HgTe CQDs solution in toluene was mixed with 1 mL of exchange solution (1.5 mg of HgCl₂, 100 μL of mercaptoethanol and 900 μL of DMF). 5 mL of hexane was added to the solution and mixed with vortex and sonication. After a few seconds, two phases were clearly visible and the hexane one was removed. The solution was cleaned with hexane one more time. At this step, 250 μL of DMF was added to avoid precipitation. The solution was cleaned again with hexane. Then, the solution was precipitated by adding ethanol and centrifuged at 6000 rpm for 4 min. Supernatant was discarded and the nanocrystals were redispersed in 150 μL of DMF.

### Example: Liqand Exchange Procedure for CdSe Nanocrystals

440 μL of CdSe nanocrystals solution in hexane (exciton optical density=0.58 after a dilution by 100) with optical properties at 640 nm were mixed with 800 μL of Na₂S solution (0.1 M in N). After mixing, 2 mL of hexane were added. The top phase was removed. The solution was washed with hexane two more times. The solution was precipitated by adding toluene (5 mL) and centrifuged at 6000 rpm for 2 min. The supernatant was discarded and the nanocrystals were redispersed in 100 μL of DMF. 5 mL of toluene were added and the nanoparticles were precipitated at 6000 rpm for 2 min. The supernatant was discarded and the nanocrystals were redispersed in 100 μL of DMF.

### Example: Preparation of Undoped SnO₂ Solution (Dilution by 3) (SnO₂-P)

400 μL of SnO₂ nanoparticle solution (15% in water) marketed by the company Alfa Aeser was diluted with 0.8 mL of distilled water.

### Example: Preparation of Low-Doped SnO₂ Solution (Dilution by 3) (SnO₂-L′)

400 μL of SnO₂ nanoparticle solution (15% in water) marketed by Alfa Aeser was mixed with 0.8 mL of 24 mM NH₄Cl solution in distilled water.

### Example: Preparation of Low-Doped SnO₂ Solution (Dilution Par 6) (SnO₂-L″)

200 μL of SnO₂ nanoparticle solution (15% in water) marketed by Alfa Aeser was mixed with 1 mL of 24 mM NH₄X (X=Cl, Br and I) solution in distilled water.

### Example: Preparation of High-Doped SnO₂ Solution (Dilution by 3) (SnO₂-H)

200 μL of SnO₂ nanoparticle solution (15% in water) marketed by Alfa Aeser was mixed with 1 mL of NH₄X (X=Cl, Br and I) solution at 48 mM in distilled water.

### Example: Manufacture of an FTO («Fluorine Doped Tin Oxide») Electrode

The electrodes were fabricated using standard optical lithography methods. The surface of an FTO substrate (70 nm thick) on glass was cleaned by ultrasonication in acetone. The substrate was rinsed with isopropanol and finally cleaned using 02 plasma. The adhesion promoter (Ti-prime) was deposited by spin coating and baked at 120° C. for 180 s. The resist marketed as AZ®5214E by Merck was spin-coated and cured at 110° C. for 90 s. The substrate was exposed to UV light through a patterned mask for 20 s. The resist was developed using a bath marketed as AZ®726 by Merck for 30 s, before being rinsed with pure water. The FTO was then etched using reactive ion etching. The patterning was achieved by soaking the film for 15 min in acetone. The electrodes were then rinsed with isopropanol and dried by nitrogen flow.

### Example: Manufacture of an ITO («Indium Tin Oxide») Electrode

Electrodes were fabricated using standard optical lithography methods. The surface of a ITO (40 nm thick) on glass substrate was cleaned by sonication in acetone.

The substrate was rinsed with isopropanol and finally cleaned using a 02 plasma. Ti prime was deposited via spin coating and baked at 120° C. for 180 s. The resist marketed under the name AZ®5214E by Merck was spin-coated and baked at 110° C. for 90 s. The substrate was exposed under UV through a pattern mask for 20 s. The resist was developed using a bath marketed under the name AZ®726 by Merck for 30 s, before being rinsed with pure water. The ITO was etched with HCl bath (25%) at 40° C. for 2 min. The lift-off is performed by dipping the film for 15 min in acetone. The electrodes were finally rinsed using isopropanol and dried by nitrogen flow.

### Example: Manufacture of a Photodetector (CdSe Electron Extraction Layer)

The FTO-coated glass substrates were sequentially cleaned in acetone and isopropanol. The substrates were exposed to ozone plasma for 10 min. The CdSe ink was deposited onto the patterned FTO substrate via spin coating (800 rpm for 2 min). The CdSe film was annealed on a hot plate at 200° C. for 20 min. The HgTe nanocrystals ink was deposited onto the CdSe film via spin coating at room temperature. The thickness of the film was tuned with spin coating speed and ink concentration in DMF solvent. On top of HgTe ink film, a Ag₂Te nanocrystals layer was spin coated at 2000 rpm followed by HgCl₂ treatment. For HgCl₂ treatment, 50 μL of HgCl₂ methanol (10 mM) solution was dropped onto HgTe film and spin-dried after 15 s. Then the film was rinsed with isopropanol. This procedure was repeated one more time. Finally, an ethanedithiol ligand-exchange was performed by dipping the film in 1% ethanedithiol in acetonitrile solution for 30 s and rinsed with pure acetonitrile. An 80 nm Au top electrode was deposited with thermal evaporation under a vacuum of ≈5×10⁻⁶ mbar at the rate of 3 A/s. The thickness was monitored with in situ quartz crystals. The substrate holder was rotated during the deposition to ensure homogeneous thickness.

### Example: Manufacture of a Photodetector (CdSe Electron Extraction Laver and ITO Electrode)

The ITO-coated glass substrates were sequentially cleaned in acetone and isopropanol. The substrates were exposed to ozone plasma for 10 min. The CdSe ink was deposited onto the patterned ITO substrate via spin coating (800 rpm for 2 min). The CdSe film was annealed on a hot plate at 200° C. for 20 min. The HgTe nanocrystals ink was deposited onto the CdSe film via spin coating. The thickness of the film was tuned with spin-coating speed and ink concentration in DMF solvent. On top of HgTe ink film, Ag₂Te nanocrystals layer was spin-coated at 2000 rpm followed by HgCl₂ treatment. For HgCl₂ treatment, 50 μL of HgCl₂ methanol (10 mM) solution was dropped onto HgTe film and spin-dried after 15 s. Then the film was rinsed with isopropanol. This procedure was repeated one more time. Finally, an ethanedithiol ligand-exchange was performed by dipping the film in 1% ethanedithiol in acetonitrile solution for 30 s and rinsed with pure acetonitrile. An 80 nm Au top electrode was deposited with thermal evaporation under a vacuum of =5×10⁻⁶ mbar at the rate of 3 A/s. The thickness was monitored with in situ quartz crystals. The substrate holder was rotated during the deposition to ensure homogeneous thickness.

### Example: Manufacture of a Photodetector (SnO₂ Electron Extraction Layer)

The FTO-coated glass substrates were sequentially cleaned in acetone and isopropanol. The substrates were exposed to ozone plasma for 10 min. The SnO₂-L″ solution was deposited onto the patterned FTO substrate via spin-coating. The SnO₂-H solution was deposited onto the SnO₂-L layer. The film was annealed on a hot plate at 70° C. The HgTe nanocrystals ink was deposited onto the SnO₂ film via spin coating. The thickness of the film was tuned with spin coating speed and ink concentration in DMF solvent. On top of HgTe ink film, Ag₂Te nanocrystals layer was spin-coated at 2000 rpm followed by HgCl₂ treatment. For HgCl₂ treatment, 50 μL of HgCl₂ methanol (10 mM) solution was dropped onto HgTe film and spin-dried after 15 s. Then the film was rinsed with isopropanol. This procedure was repeated one more time. Finally, an ethanedithiol ligand-exchange was performed by dipping the film in 1% ethanedithiol in acetonitrile solution for 30 s and rinsed with pure acetonitrile. An 80 nm Au top electrode was deposited with thermal evaporation under a vacuum of =5×10⁻⁶ mbar at the rate of 3 A/s. The thickness was monitored with in situ quartz crystals. The substrate holder was rotated during the deposition to ensure homogeneous thickness.

### Example: Manufacture of a Photodetector (SnO₂ Electron Extraction Layer and ITO Electrode)

The ITO-coated glass substrates were sequentially cleaned in acetone and isopropanol. The substrates were exposed to ozone plasma for 10 min. The SnO₂-L″ solution was deposited onto the patterned ITO substrate via spin-coating. The SnO₂-H solution was deposited onto the SnO₂-L layer. The film was annealed on a hot plate at 70° C. The HgTe nanocrystals ink was deposited onto the SnO₂ film via spin-coating. The thickness of the film was tuned with spin-coating speed and ink concentration in DMF solvent. On top of HgTe ink film, Ag₂Te nanocrystals layer was spin-coated at 2000 rpm followed by HgCl₂ treatment. For HgCl₂ treatment, 50 μL of HgCl₂ methanol (10 mM) solution was dropped onto HgTe film and spin-dried after 15 s. Then the film was rinsed with isopropanol. This procedure was repeated one more time. Finally, an ethanedithiol ligand-exchange was performed by dipping the film in 1% ethanedithiol in acetonitrile solution for 30 s and rinsed with pure acetonitrile. An 80 nm Au top electrode was deposited with thermal evaporation under a vacuum of =5×10⁻⁶ mbar at the rate of 3 A/s. The thickness was monitored with in situ quartz crystals. The substrate holder was rotated during the deposition to ensure homogeneous thickness.

### Example: Fabrication of a Photodetector (SnO₂ Electron Extraction Layer with SnO₂-P)

The FTO-coated glass substrates were sequentially cleaned in acetone and isopropanol. The substrates were exposed to ozone plasma for 10 min. The SnO₂-P solution was deposited onto the patterned FTO substrate via spin-coating. The SnO₂-L′ solution is deposited onto the SnO₂-L layer. The film was annealed on a hot plate at 70° C. The HgTe nanocrystals ink was deposited onto the SnO₂ film via spin-coating. The thickness of the film was tuned with spin-coating speed and ink concentration in DMF solvent. On top of HgTe ink film, Ag₂Te nanocrystals layer was spin-coated at 2000 rpm followed by HgCl₂ treatment. For HgCl₂ treatment, 50 μL of HgCl₂ methanol (10 mM) solution was dropped onto HgTe film and spin-dried after 15 s. Then the film was rinsed with isopropanol. This procedure was repeated one more time. Finally, an ethanedithiol ligand-exchange was performed by dipping the film in 1% ethanedithiol in acetonitrile solution for 30 s and rinsed with pure acetonitrile. An 80 nm Au top electrode was deposited with thermal evaporation under a vacuum of =5×10⁻⁶ mbar at the rate of 3 A/s. The thickness was monitored with in situ quartz crystals. The substrate holder was rotated during the deposition to ensure homogeneous thickness.

### Example: Manufacture of a Photodetector (Solid State Exchange for HqTe Layer+CdSe)

The FTO-coated glass substrates were sequentially cleaned in acetone and isopropanol. The substrates were exposed to an ozone plasma for 10 minutes. The CdSe ink was deposited onto the patterned FTO substrate by centrifugation (800 rpm for 2 min). The CdSe film was annealed on a hot plate at 200° C. for 20 min. 80 μL of concentrated HgTe nanocrystals (25 mg/mL) from toluene were deposited by centrifugation at 2000 rpm for 30 s on the CdSe film. After complete evaporation of the solvent, ligand exchange is performed by dipping the film in a 1-2 wt % ethanedithiol solution in ethanol for 90 s and rinsing in pure ethanol for 30 s. This procedure is repeated 8-9 times to obtain a thicker HgTe film (180-200 nm) without holes. On the HgTe film, a layer of Ag₂Te nanocrystals was deposited by centrifugation at 2000 rpm followed by HgCl₂ treatment. For the HgCl₂ treatment, 50 μL of HgCl₂-methanol (10 mM) solution was deposited on the HgTe film and spun off after 15 s. Then the film was rinsed with isopropanol. This procedure was repeated once more. Finally, an ethanedithiol ligand exchange was performed by dipping the film in a solution of ethanedithiol in 1% acetonitrile for 30 s and rinsing with pure acetonitrile. An 80 nm Au top electrode was deposited by thermal evaporation under a vacuum of ≈5×10⁻⁶ mbar at the rate of 3 A/s. The thickness was controlled with quartz crystals in situ. The substrate holder was rotated during deposition to ensure a homogeneous thickness.

### Example: Manufacture of a Photodetector (Solid State Exchange for the HqTe Layer+Sno₂)

The FTO-coated glass substrates were sequentially cleaned in acetone and isopropanol. The substrates were exposed to an ozone plasma for 10 minutes. The SnO₂-L solution was deposited onto the patterned FTO substrate by spin coating. The SnO₂-L″ solution was deposited on the SnO₂-L layer. The film was annealed on a hot plate at 70° C. 80 μL of concentrated HgTe nanocrystals (25 mg/mL) from toluene were deposited by spin coating at 2000 rpm for 30 s on the above SnO₂ layer. After complete evaporation of the solvent, ligand exchange is performed by dipping the film in a 1-2 wt % ethanedithiol solution in ethanol for 90 s and rinsing in pure ethanol for 30 s. This procedure is repeated 8-9 times to obtain a thicker HgTe film (180-200 nm) without holes. On the HgTe film, a layer of Ag₂Te nanocrystals was deposited by centrifugation at 2000 rpm followed by HgCl₂ treatment. For the HgCl₂ treatment, 50 μL of HgCl₂-methanol (10 mM) solution was deposited on the HgTe film and spun off after 15 s. Then the film was rinsed with isopropanol. This procedure was repeated once more. Finally, an ethanedithiol ligand exchange was performed by dipping the film in a 1% ethanedithiol in acetonitrile solution for 30 s and rinsing with pure acetonitrile. An 80 nm Au top electrode was deposited by thermal evaporation under a vacuum of ≈5×10⁻⁶ mbar at the rate of 3 A/s. The thickness was controlled with quartz crystals in situ. The substrate holder was rotated during deposition to ensure a homogeneous thickness.

### Example: Manufacture of a Diode Array

A CMOS technology readout circuit is cleaned by oxygen plasma for 10 min. A layer of Ag₂Te nanocrystals was deposited by centrifugation at 2000 rpm, followed by HgCl₂ treatment. For the HgCl₂ treatment, 50 μL of HgCl₂ methanol solution (10 mM) was deposited on the HgTe film and blotted after 15 s. Then the film was rinsed with isopropanol. The HgTe nanocrystals ink was deposited on the Ag₂Te nanocrystal film by spin coating. The thickness of the film was adjusted according to the application speed and the concentration of the ink in the DMF solvent. On the HgTe nanocrystal layer, the SnO₂-H solution was deposited by spin coating. On the SnO₂-H nanocrystal layer, the SnO₂-L solution was deposited by spin coating. Using plasma assisted deposition, a thin layer of ITO was deposited to form a continuous layer of 50 nm.

### Example: Manufacture of a Diode Array

A CMOS technology readout circuit is terminated with Au top contact and cleaned by oxygen plasma for 10 min. On the CMOS circuit, a SnO₂ solution was deposited by spin coating. The HgTe nanocrystals ink was deposited on the SnO₂ nanocrystal film by spin coating. A layer of Ag₂Te nanocrystals was deposited by centrifugation at 2000 rpm, followed by HgCl₂ treatment. For the HgCl₂ treatment, 50 μL of HgCl₂ methanol solution (10 mM) was deposited on the HgTe film and blotted after 15 s. Then the film was rinsed with isopropanol. Using sputtering deposition, a thin layer of ITO was deposited to form a continuous layer of 50 nm.

### Example: Manufacture of a Diode Array

A CMOS technology readout circuit is terminated with Al top contact and cleaned by oxygen plasma for 10 min. On the CMOS circuit, a SnO₂ solution was deposited by spin coating. The HgTe nanocrystals ink was deposited on the SnO₂ nanocrystal film by spin coating. A layer of Ag₂Te nanocrystals was deposited by centrifugation at 2000 rpm, followed by HgCl₂ treatment. For the HgCl₂ treatment, 50 μL of HgCl₂ methanol solution (10 mM) was deposited on the HgTe film and blotted after 15 s. Then the film was rinsed with isopropanol. Using sputtering deposition, a thin layer of ITO was deposited to form a continuous layer of 50 nm.

1. Infrared photodetector, comprising an electron transport layer and an infrared photon absorption layer for generating an electrical signal, characterized in that the electron transport layer comprises nanocrystals of a compound selected from SnO₂, ZnO, CdS, CdSe, aluminium-doped zinc oxide, Cr₂O₃, CuO, CuO₂, Cu₂O₃, ZrO₂, and mixture thereof and heterostructure thereof and alloy thereof, and in that the infrared photon absorption layer comprises nanocrystals of a compound selected from HgS, HgSe, HgTe, PbS, PbSe, PbTe, Ag₂S, Ag₂Se, Ag₂Te, InAs, InGaAs and InSb and mixture thereof, and heterostructure thereof and alloy thereof.

2. Photodetector according to claim 1, characterized in that the infrared photon absorption layer comprises HgTe nanocrystals and in that the electron transport layer comprises CdSe or SnO₂ nanocrystals.

3. Photodetector according to claim 1, characterized in that the offset between the conduction band of the electron transport layer and the conduction band of the infrared photon absorption layer is less than 1 eV, preferably less than 0.3 eV and more preferably less than 0.1 eV.

4. Photodetector according to claim 1, characterized in that it comprises:
a mechanical substrate layer,
an electron contact layer constituting a top electrode,
the electron transport layer,
the infrared photon absorption layer for generating an electrical signal,
a hole transport layer,
a metallic contact layer for collecting charges, which forms a bottom electrode.

5. Photodetector according to claim 4, characterized in that the mechanical substrate layer comprises a compound selected from glass, CaF₂, undoped Si, undoped Ge, ZnSe, ZnS, KBr, LiF, Al₂O₃, KCl, BaF₂, CdTe, NaCl, CsBr, MgF₂, quartz, CdZnTe, InP, GaAs, thalium bromoiodide, and heterostructure thereof and alloy thereof.

6. Photodetector according to claim 4, characterized in that the electron transport layer has a thickness of between 0.5 and 500 nm.

7. Photodetector according to claim 4, characterized in that the infrared photon absorption layer has a thickness of between 1 nm and 1 μm.

8. Photodetector according to claim 7, characterized in that the infrared photon absorption layer has an optical gap between 1 and 3 μm, and preferably between 1.5 and 2.5 μm.

9. Photodetector according to claim 4, characterized in that the hole transport layer has thickness of between 0.5 nm and 500 nm.

10. Photodetector according to claim 4, characterized in that the metallic contact layer has a thickness of between 1 and 10 μm, and preferably of between 10 nm and 3 μm.

11. Photodetector according to claim 1, characterized in that the photodetector is a photodiode.

12. Photodetector according to claim 1, where the infrared photon absorption layer is coupled to a light resonator.

13. Imaging device, characterized in that it comprises a plurality of photodetectors according to claim 1, configured to form an image.

14. Imaging device according to claim 13, characterized in that the plurality of photodetectors is coupled to a readout circuit.

15. Camera device, characterized it comprises a plurality of photodetectors according to claim 1, configured to form a camera.

16. Camera device according to claim 15, characterized in that the plurality of photodetectors is coupled to an electronic system, an optical system, and a temperature control system.
